(19) United States
(12) Patent Application Publication
(10) Pub. No.: US 2026/0236813 A1
(43) Pub. Date: Aug. 13, 2026

(54) TWO-DIMENSIONAL CONVEYOR-MODE SPIN QUBIT SHUTTLING DEVICES

(71) Applicant: Wisconsin Alumni Research Foundation, Madison, WI (US)

(72) Inventors: Mark A. Eriksson, Madison, WI (US); Mark G. Friesen, Middleton, WI (US); Merritt Losert, Madison, WI (US); Vatsal K. Bandaru, Danbury, CT (US)

(21) Appl. No.: 18/975,615

(22) Filed: Dec. 10, 2024

(51) Int. Cl. G06N 10/40; H10D 48/00

(52) U.S. Cl. CPC G06N 10/40; H10D 48/3835

(57) ABSTRACT

Spin qubit shuttling devices and methods for their use are provided. The devices enable the electrons of an electron spin qubit to be translated in a two-dimensional (2D) plane with high spin fidelities. The 2D translational motion can be used to maneuver the electrons around low valley splitting regions in a semiconductor channel and/or to bring electrons in a qubit processor into close proximity to allow for spin coupling beyond nearest neighbor interactions. As such, the spin qubit shuttling devices have applications in quantum computing systems, including in quantum links and qubit registers.

### REFERENCE TO GOVERNMENT RIGHTS

This invention was made with government support under W911NF-22-1-0090 awarded by the ARMY/ARO. The government has certain rights in the invention.

### BACKGROUND

Quantum dots formed in semiconductor heterostructures are a promising platform for quantum computing systems. Spin qubits formed in Si/SiGe heterostructures are particularly well suited for quantum computing applications because silicon and germanium have abundant zero-spin isotopes and are compatible with existing semiconductor fabrication technologies. However, the need to couple distant qubits, which is not possible via short-ranged exchange interactions, makes the scale-up of quantum computing systems challenging. For this reason, there is considerable interest in developing quantum computing systems that are capable of coupling qubits beyond their nearest neighbors.

Conveyor mode shuttling of qubits over micron-scale distances is one approach that has been proposed to expand qubit coupling beyond nearest neighbor interactions. In conveyor mode qubit shuttling, phase-shifted sinusoidal potentials are applied to interleaved Clavier gates to form a shuttling channel defined between screening gates. The applied potentials generate a moving potential well that transports an electron in one-dimension along the channel. (Langrock, Veit, et al. “Blueprint of a scalable spin qubit shuttle device for coherent mid-range qubit transfer in disordered Si/SiGe/SiO₂.” PRX Quantum 4.2(2023 ): 020305; and Losert, Merritt P., et al. “Strategies for enhancing spin-shuttling fidelities in Si/SiGe quantum wells with random-alloy disorder.” PRX Quantum 5.4(2024 ): 040322.)

A major challenge for electron shuttling in Si/SiGe-based qubits is the dephasing of the electron spin wavefunction and reduced shuttling fidelity caused by low-lying valley states in silicon. Valley splitting, which is the energy spacing between the nearly degenerate low-lying valley states, can vary widely within a semiconductor heterostructure. These variations result in local regions having low valley splittings that pose a challenge for achieving spin-coherent electron shuttling over extended distances. (Zwanenburg, Floris A., et al. “Silicon quantum electronics.” Reviews of modern physics 85.3(2013 ): 961-1019; Burkard, Guido, et al. “Semiconductor spin qubits.” Reviews of Modern Physics 95.2(2023 ): 025003; Paquelet Wuetz, Brian, et al. “Atomic fluctuations lifting the energy degeneracy in Si/SiGe quantum dots.” Nature Communications 13.1(2022 ): 7730; Losert, Merritt P., et al. “Practical strategies for enhancing the valley splitting in Si/SiGe quantum wells.” Physical Review B 108.12(2023 ): 125405; Lima, Jonas RF, and Guido Burkard. “Interface and electromagnetic effects in the valley splitting of Si quantum dots.” Materials for Quantum Technology 3.2(2023 ): 025004; Peña, Luis Fabián, et al. “ Modeling Si/SiGe quantum dot variability induced by interface disorder reconstructed from multiperspective microscopy.” npj Quantum Information 10 (2024): 33; and Volmer, Mats, et al. “Mapping of valley splitting by conveyor-mode spin-coherent electron shuttling.” npj Quantum Information 10.1(2024 ): 61)

Another challenge hindering the scaling-up of spin qubit-based quantum computing architectures is the need to provide gate electrodes and signal lines for a large number of qubits within a very limited space. This hurdle in scale-up is known as the fan-out problem.

Thus, a need exists for a quantum computing system that increases qubit coupling capabilities and reduces spin decoherence due to valley splitting without exacerbating the fan-out problem.

### SUMMARY

Spin qubit shuttling devices, quantum computing systems incorporating the devices, and methods for using the devices in shuttle spin qubits are provided.

One embodiment of a spin qubit shuttling device includes: a spin qubit heterostructure; a two-dimensional assembly of shuttle tiles on the spin qubit heterostructure, each shuttle tile comprising a two-dimensional array of Clavier gates, wherein each Clavier gate in each shuttle tile is connected to a corresponding Clavier gate in each of the other shuttle tiles via a signal line, such that the connected, corresponding Clavier gates form a plurality of Clavier gate sets; and one or more voltage sources configured to deliver AC signals to the Clavier gate sets via the signal lines, wherein the AC signal delivered to each Clavier gate set is phase-shifted with respect to the AC signals delivered to the other Clavier gate sets.

One embodiment of a quantum computing system includes: at least one spin qubit register or at least two spin qubit registers and a quantum link connecting the at least two qubit registers; and a spin qubit shuttling device of a type disclosed herein incorporated into at least one of the spin qubit registers or the quantum link.

One embodiment of a method of shuttling spin qubits using a spin qubit shuttling device of a type disclosed herein includes the steps of: applying gate potentials to the first screening gate and the second screening gate to form one or more spin qubits in the spin qubit heterostructure via electrostatic confinement of one or more electrons in the spin qubit heterostructure; and delivering an AC signal to each Clavier gate set, wherein the AC signal delivered to each Clavier gate set is phase-shifted with respect to the AC signals delivered to the other Clavier gate sets, whereby the phase-shifted AC signals form potential wells that move in two lateral dimensions within the spin qubit heterostructure and transport the one or more spin qubits in two lateral dimensions through the spin qubit heterostructure.

Another embodiment of a spin qubit shuttling device includes: a spin qubit heterostructure; a one-dimensional series of shuttle tiles on the spin qubit heterostructure, each shuttle tile comprising a one-dimensional sequence of Clavier gates, wherein each Clavier gate in each shuttle tile is connected to a corresponding Clavier gate in each of the other shuttle tiles via a signal line, such that the connected, corresponding Clavier gates form a plurality of Clavier gate sets; one or more voltage sources configured to deliver AC signals to the Clavier gate sets via the signal lines, wherein the AC signal delivered to each Clavier gate set is phase-shifted with respect to the AC signals delivered to the other Clavier gate sets; a first transverse screening gate along an edge of the one-dimensional series of shuttle tiles; a second transverse screening gate along an opposing edge of the one-dimensional series of shuttle tiles; a segmented screening gate on the one-dimensional series of shuttle tiles and running between the first transverse screening gate and the second transverse screening gate, the segmented screening gate comprising a plurality of individually electronically addressable gate segments; and one or more voltage sources configured to deliver gate voltages to the first and second transverse screening gates and the gate segments of the segmented screening gate.

Another embodiment of a method of shuttling spin qubits using a spin qubit shuttling device of a type disclosed herein includes the steps of: applying gate potentials to the first transverse screening gate, the second transverse screening gate, and the gate segments of the segmented screening gate to define a first shuttle channel between the first transverse screening gate and the segmented screening gate and a second shuttle channel between the segmented screening gate and the second transverse screening gate and to form one or more spin qubits in the spin qubit heterostructure via electrostatic confinement of one or more electrons in the first and second shuttle channels; delivering an AC signal to each Clavier gate set, wherein the AC signal delivered to each Clavier gate set is phase-shifted with respect to the AC signals delivered to the other Clavier gate sets, whereby the phase-shifted AC signals form potential wells that move along the first and second channels within the spin qubit heterostructure and transport the one or more spin qubits in one dimension through the spin qubit heterostructure along the first and second channels; and adjusting the gate potential applied to the gate segments of the segmented screening gate to reduce a tunneling potential between the first and second channels, whereby one or more spin qubits move laterally between the first and second channels via quantum tunneling of one or more of the electrons.

Other principal features and advantages of the invention will become apparent to those skilled in the art upon review of the following drawings, the detailed description, and the appended claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Illustrative embodiments of the invention will hereafter be described with reference to the accompanying drawings, wherein like numerals denote like elements.

FIG. 1A is a schematic diagram showing a top view (upper left) and a cross-sectional view through line a-a′ (lower right) of an assembly of electron shuttle tiles on a qubit heterostructure.

FIG. 1B is a schematic diagram of a single electron shuttle tile in the shuttle tile assembly of FIG. 1A, wherein the shuttle tile comprises of a 4-×-4 array of Clavier gates.

FIGS. 2A and 2B show simulated potential wells formed in a spin qubit heterostructure, for one snapshot in time, during an application of AC voltage signals to the Clavier gate sets in the electron shuttle tile assembly of FIG. 1A.

FIGS. 3A and 3B show snapshots of the electron density (FIG. 3A) and the moving potential (FIG. 3B) in the xy-plane of a spin qubit heterostructure at three time points, as described in Example 1.

FIG. 4A shows an assembly of electron shuttle tiles arranged in a circle. The potential generated in the xy-plane of a spin qubit heterostructure underlying the shuttle tiles at three different times are shown in FIG. 4B (electron density) and FIG. 4C (potential).

FIG. 5 is a schematic illustration of a quantum register that includes multiple quantum dots distributed within a spin qubit heterostructure and an overlying assembly of electron shuttle tiles.

FIG. 6 shows a tile assembly for a spin qubit shuttling device comprising a 3-by-5 assembly of electron shuttle tiles. Regions of the underlying electron spin qubit heterostructure having a low valley splitting are indicated by a circle-backslash symbol, and the shuttling path of an electron through the underlying electron spin qubit heterostructure is shown with a solid line.

FIG. 7A is a schematic diagram of an embodiment of a channel-forming series of electron shuttle tiles and the screening gates for a spin qubit shuttling device having two shuttling channels.

FIGS. 7B and 7C show snapshots of the electron density (FIG. 7B) and the moving potential (FIG. 7C) in the xy-plane of a spin qubit heterostructure at three different times, as described in Example 2.

FIG. 8 shows the spin qubit heterostructure used in the simulations of Example 1 and Example 2.

### DETAILED DESCRIPTION

Spin qubit shuttling devices and methods for their use are provided. The devices enable the electrons of an electron spin qubit to be translated in a two-dimensional (2D) plane with high spin fidelities. The 2D translational motion can be used to maneuver the electrons around low valley splitting regions in a semiconductor channel and/or to bring electrons in a qubit processor into close proximity to allow for spin coupling beyond nearest neighbor interactions. As such, the spin qubit shuttling devices have applications in quantum computing systems, including in quantum links and qubit registers.

In some embodiments of the spin qubit shuttling devices, the 2D translational motion is accomplished using assemblies of 2D Clavier gate arrays, while in other embodiments, the 2D translation motion is accomplished using multiple Clavier gate channels.

Spin Qubit Shuttling Using Two-Dimensional Clavier Gate Arrays

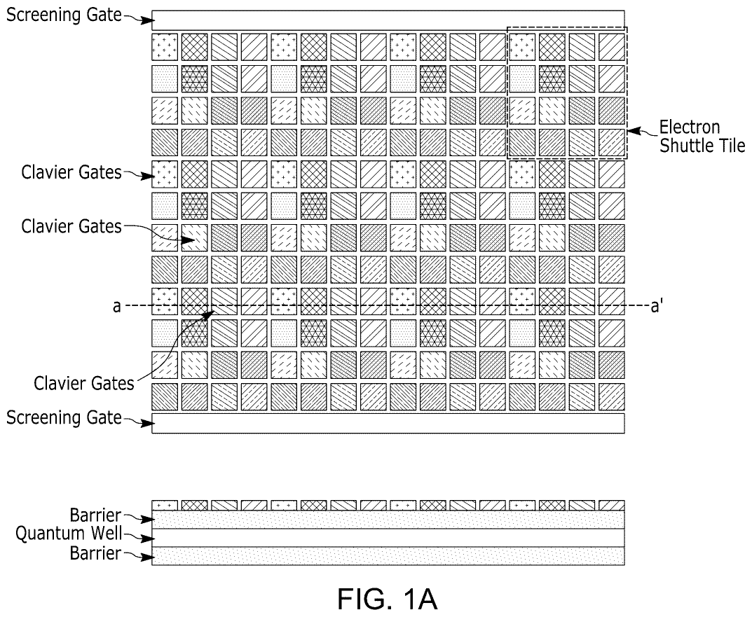

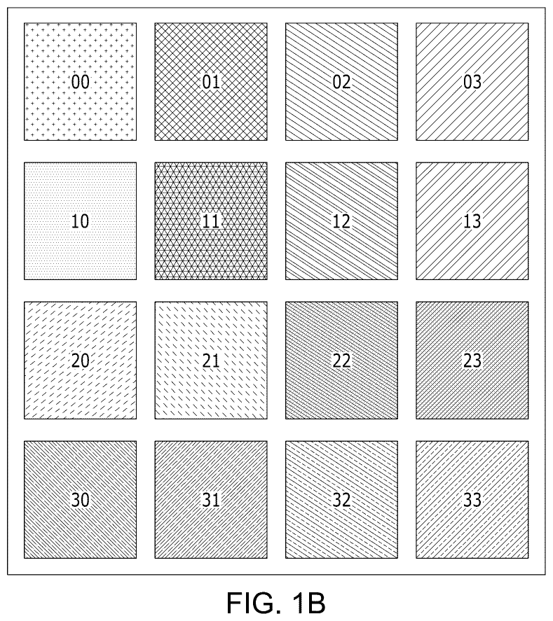

One basic embodiment of a spin qubit shuttling device includes an electron spin qubit heterostructure and a 2D assembly of electron shuttle tiles on the electron spin qubit heterostructure. Each electron shuttle tile includes a 2D array of gate electrodes, referred to herein as Clavier gates. Each Clavier gate in a tile is individually addressable and connected to a signal line through which an AC signal is delivered. Each Clavier gate in a given electron shuttle tile is connected to a corresponding Clavier gate in the other electron shuttle tiles of the assembly to form a set of corresponding Clavier gates (“a Clavier gate set”). This is illustrated schematically in FIG. 1A, where Clavier gates depicted with the same pattern form a Clavier gate set. The Clavier gates that constitute a Clavier gate set receive the same AC signal, preferably through the same signal line. One or more voltage sources in electrical communication with the signal lines generate the AC signals.

The AC signal delivered to a given Clavier gate set is phase-shifted with respect to the AC signals delivered to the other Clavier gate sets, such that these signals generate a dynamic potential landscape in the electron spin qubit heterostructure that can be used to move one or more qubits laterally, in two dimensions, through the heterostructure. Optionally, screening gates may be provided along the lateral edges of the electron shuttle tile assembly to define the boundaries of a channel in the spin qubit heterostructure in which the electrons can be moved.

The spin qubit heterostructure includes stacked semiconductor layers that form a quantum well in a multilayered structure in which a quantum well layer is sandwiched between barrier layers. Electrons are confined in three dimensions within the quantum well; the quantum well provides confinement in one direction (the z-direction), and confinement in the other two dimensions (the x- and y-directions) is provided by the application of gate voltages to gate electrodes on the heterostructure. The electrostatically confined electrons are referred to as quantum dots. The confinement of the electrons of a quantum dot results in bound states with discrete energy levels, and the spin wavefunctions describing these states can be utilized to establish a quantum two-level system that serves as a qubit to encode information in a quantum computing system. A detailed description of electron spin qubits and their use in quantum computing can be found, for example, in Vandersypen, Lieven MK, and Mark A. Eriksson. “Quantum computing with semiconductor spins.” Physics Today 72.8 (2019): 38-45.

Electron spin qubit heterostructures are commonly composed of layers of silicon (Si) and silicon germanium (SiGe), in which a Si quantum well layer is sandwiched between SiGe barrier layers. In other embodiments the quantum well layer may be Ge, or the quantum well layer and the barrier layers may be SiGe alloys in which the alloys have different Ge concentrations. Illustrative examples of electron spin qubit heterostructures can be found in US patent application publication number 2023/0085706 and Losert, Merritt P., et al. “Practical strategies for enhancing the valley splitting in Si/SiGe quantum wells.” Physical Review B 108.12(2023 ): 125405. The use of Si-based spin qubit heterostructures is advantageous because silicon processing is widely used in the semiconductor device industry and because qubits in these heterostructures have long coherence times. However, other semiconductors can be used in the spin qubit heterostructures, including systems formed of AlGaAs/GaAs layers, Si/SiO₂ layers, Ge/SiGe heterostructures, and two-dimensional materials, such as those formed of graphene or bilayer graphene. Spin qubit heterostructures having a metal-oxide-semiconductor (MOS) design comprising metal oxide barriers can also be used.

The phase shifted AC signals applied to the Clavier gate sets in the electron shuttle tiles control the potential landscape experienced by a qubit in the electron spin heterostructure. These phase-shifted AC signals create dynamic potential wells in the spin qubit heterostructure that move electrostatically confined electrons in two lateral dimensions. In some embodiments, the phase shifted AC voltage signals are phase-shifted sinusoidal signals applied along both the x-and y-directions. The generation of moving potential wells using phase-shifted sinusoidal signals in two directions is illustrated in Example 1.

The Clavier gate array of each electron shuttle tile will include at least nine Clavier gates in a 3-gate-by-3-gate array. However, to move the qubits through extended lateral distances and to form well-defined deep and symmetric potential wells, it is desirable to use Clavier gate arrays having dimensions of at least 4 gates by 4 gates. Larger arrays can be used. However, as the number of Clavier gate sets in the electron shuttle tiles increases, so does the number of signal lines. FIG. 1B is a schematic diagram of a single electron shuttle tile comprising 16 Clavier gates arranged in a 4-by-4 array. An assembly of electron shuttle tiles, each having the Clavier gate array arrangement shown in FIG. 1B, could be operated with only 16 signal lines, which minimizes the fan out problem of more complex gate architectures.

The lateral dimensions of the Clavier gates (e.g., length and width or diameter) are typically less than 250 nm. This includes lateral Clavier gate dimensions in the range from 20 nm to 200 nm. However, Clavier gates having lateral dimensions outside of these ranges can be used.

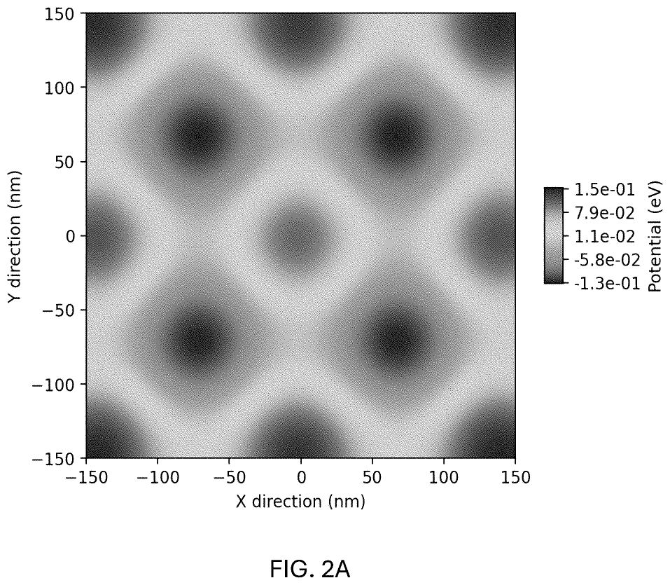

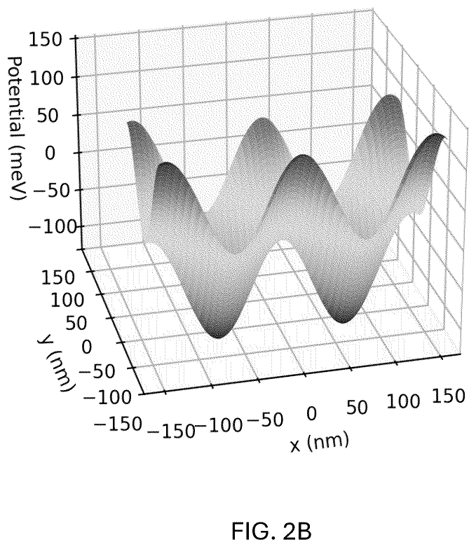

Multiple electron shuttle tiles are assembled in a 2D plane covering the distance over which electrons in the spin qubit heterostructure are to be translated. The shuttle tiles are assembled in a planar side-by-side arrangement to provide continuous paths for the moving potential wells and the qubits contained therein through the heterostructure. FIGS. 2A and 2B show simulated potential wells formed in a spin qubit heterostructure by the application of AC voltage signals to the 16 Clavier gate sets in an electron shuttle tile assembly comprising four electron shuttle tiles, each having the Clavier gate array configuration shown in FIG. 1B. (Details regarding the simulation are provided in Example 1.) The potential wells are deep, symmetric, and well-separated, which minimizes or eliminates leakage of the electrons to other energy levels and tunneling of electrons between the potential wells, thereby maximizing the fidelity of the qubit shuttling process and enabling spin-coherent shuttling.

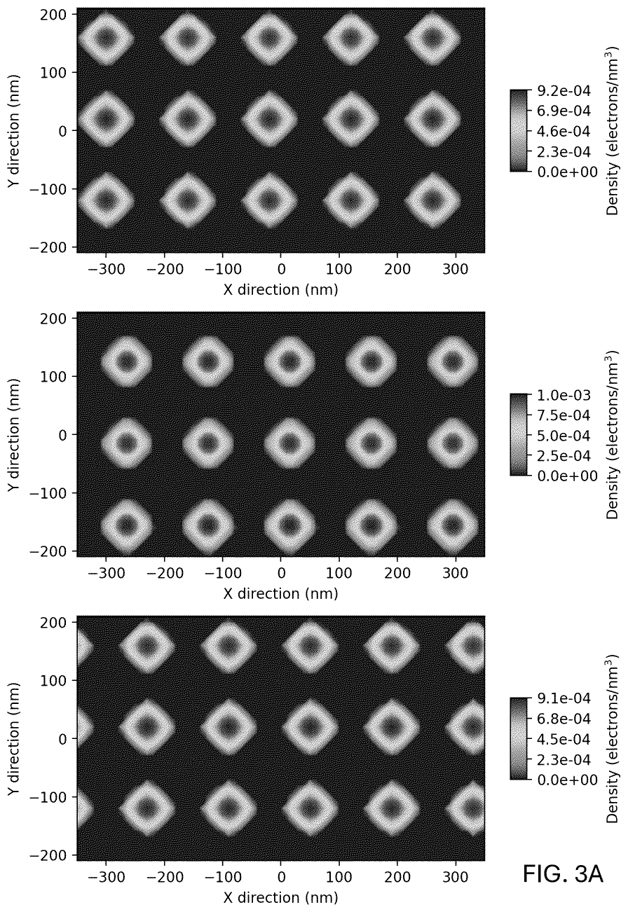

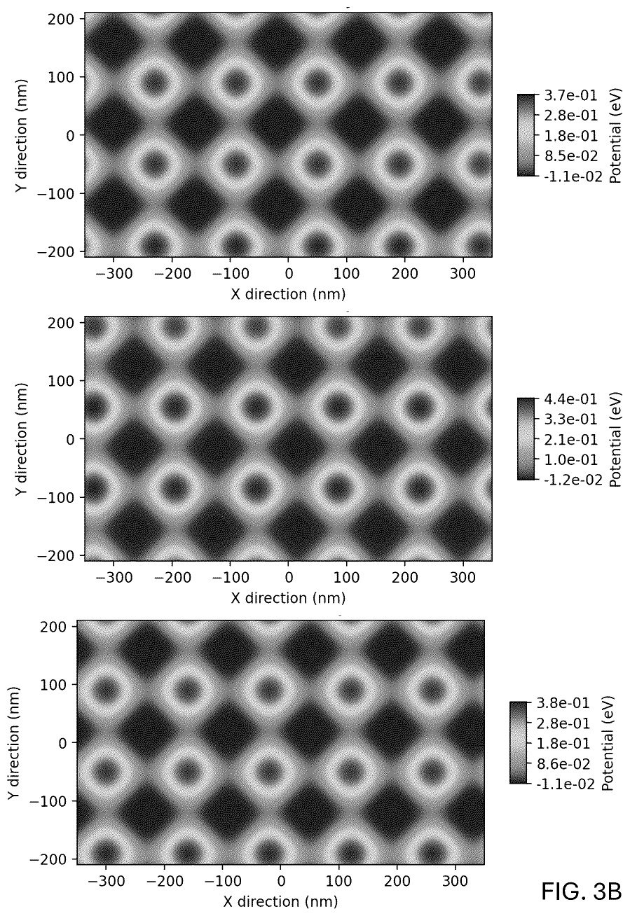

Snapshots of the electron density and the potential in the xy-plane of a spin qubit heterostructure at three different times are shown in FIG. 3A (electron density) and FIG. 3B (potential). These figures illustrate the ability of the spin qubit shuttling devices to transport electron spin qubits over long distances in two dimensions using AC signals that are periodically varied in two dimensions. The distances over which the qubit can be transported will depend on the dimensions of the Clavier gate arrays and the number of electron shuttle tiles in the assembly. By way of illustration, qubits may be shuttled over distances of at least 100 nm, at least 200 nm, at least 500 nm, at least 1 μm, at least 10 μm or further with high spin fidelity. High fidelity shuttling of the electrons can be carried out at relatively low velocities in order to minimize leakage during shuttling. Generally, shuttling velocities of 5 m/s are sufficient, including shuttling velocities in the range from 1 m/s to 5 m/s. However, shuttling velocities outside of this range may be used.

The Clavier gates are made from electrically conductive materials, such as metals or conducting metal oxides, and may be deposited and patterned on a surface of a spin qubit heterostructure using known techniques. For example, the Single Layer Etch-Defined Gate Electrode (SLEDGE) method described in Ha, Wonill, et al. “A flexible design platform for Si/SiGe exchange-only qubits with low disorder.” Nano Letters 22.3(2021 ): 1443-1448 can be used to form complex gate and signal line layouts. The Clavier gates may be, but need not be, square shaped. Other gate shapes, such as circular, hexagonal, triangular, or rectangular, can also be used. The Clavier gates typically have nanoscale lateral dimensions (e.g., lengths and widths for rectangular gates or diameters for circular gates) in the range from about 10 nm to about 150 nm. However, gates with dimensions outside of this range can be used.

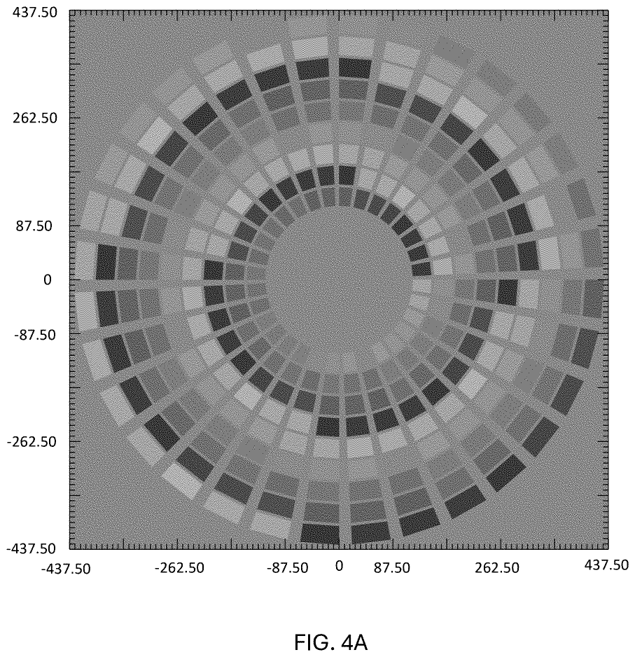

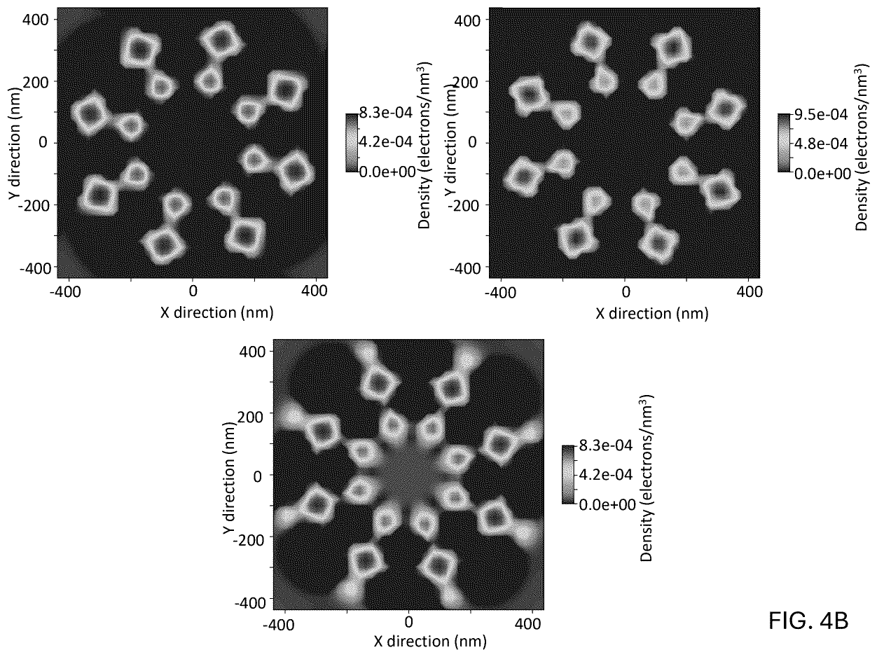

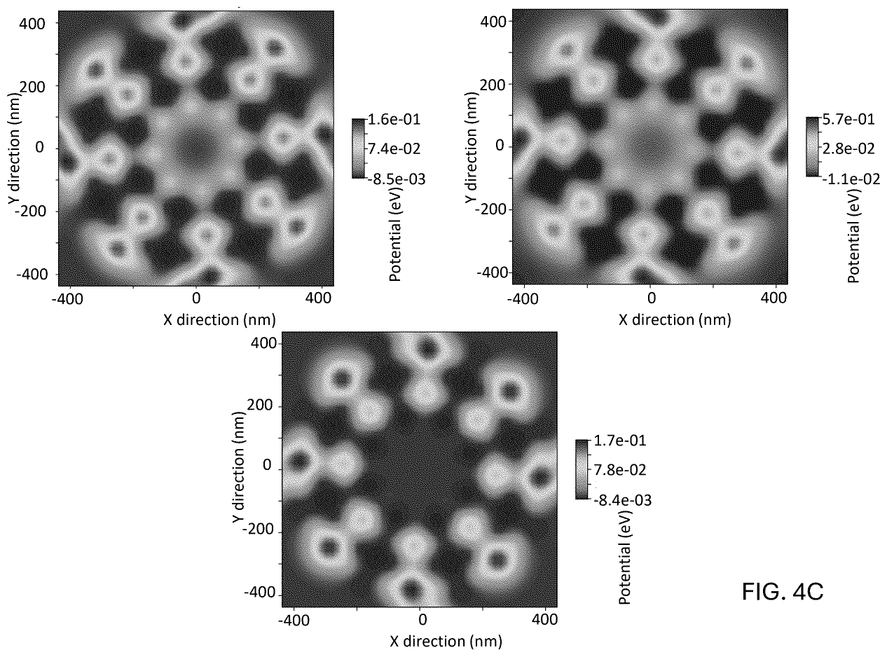

For movement in a primarily straight path, the shuttle tiles in an assembly may be arranged in a rectangle or square matrix. An example of a rectangular matrix of tiles is shown in FIG. 1A, wherein the shuttle tile assembly is composed of a 3-tile-by-4-tile rectangular matrix. However, the assemblies may be arranged in more complex and even non-geometric shapes to provide more complex paths for the qubits in the heterostructure. By way of illustration, the electron shuttle tiles may be arranged in a circle or a spiral pattern. An illustrative electron spin shuttling device comprising a plurality of spin shuttle tiles arranged in a spiral pattern is shown in FIG. 4A. The potential landscape generated in the xy-plane of a spin qubit heterostructure underlying the shuttle tiles at three different times is shown in FIG. 4B (electron density) and FIG. 4C (potential). These figures illustrate the ability of the spin qubit shuttling devices to transport electron spin qubits smoothly and continuously along complex paths in a 2D plane.

The ability to transport spin-coherent electrons in two lateral dimensions in a spin qubit heterostructure may be beneficial for a variety of reasons. For example, the electrons in the moving potential wells may be carried from one location in a spin qubit heterostructure to another to enable the coupling of qubits that would otherwise be too distant to permit wavefunction overlap. The 2D lateral movement of the qubit can also be used to transport a qubit along a complex 2D path and/or a 2D path that avoids regions of low valley splitting, or other undesirable features, within the quantum well of the spin qubit heterostructure.

One or more spin qubit shuttling devices of the type described herein can be incorporated into a quantum network in which two or more qubit registers are interconnected via quantum links. In a quantum network, quantum registers are densely packed collections of qubits that operate in unison to perform calculations via qubit manipulations, and these registers are connected to one another by quantum links. (See, for example, Vandersypen, L. M. K., et al. “Interfacing spin qubits in quantum dots and donors—hot, dense, and coherent.” npj Quantum Information 3.1(2017 ): 34; and Vandersypen, Lieven MK, and Mark A. Eriksson. “Quantum computing with semiconductor spins.” Physics Today 72.8(2019 ): 38-45.)

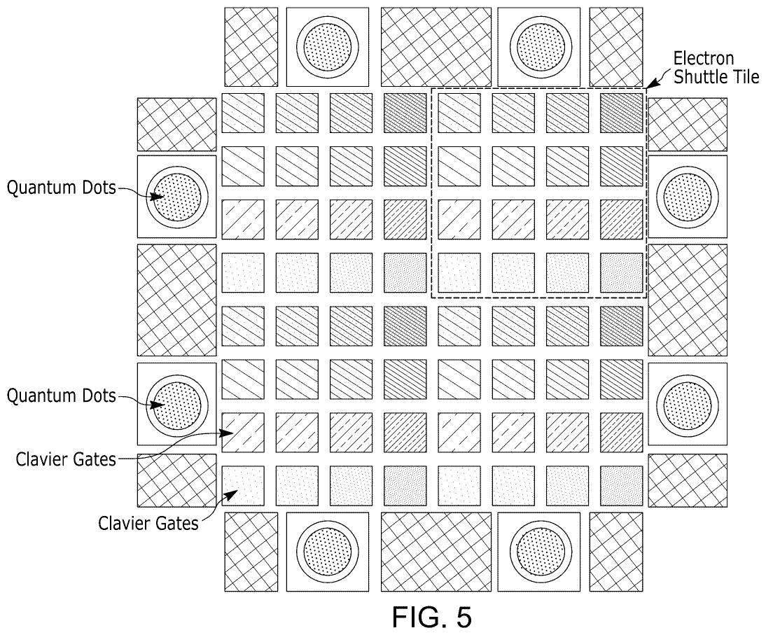

A qubit shuttling device incorporated into a quantum register can be designed to move single electrons sequentially or multiple electrons simultaneously. Electron shuttling in a spin qubit heterostructure can be omni-directional in a lateral plane, enabling “all-to-all” coupling between qubits in a quantum register. This is illustrated schematically in FIG. 5, which shows a collection of quantum dots distributed within a spin qubit register. The quantum dots are separated and disposed around the periphery of a central region of a spin qubit heterostructure. An electron shuttle time assembly comprising four electron shuttle tiles is disposed on a surface of the heterostructure over the central region. In the device shown here, each shuttle tile contains a four-by-four array of Clavier gates. By applying phase-shifted AC signals in two dimensions to the Clavier gate sets in the tiles, omni-directional qubit shuttling can be used to bring each electron spin qubit into proximity with any other electron spin qubit to enable qubit coupling. While the spin qubit shuttling device of FIG. 5 includes eight qubits, four electron shuttle tiles, and Clavier arrays having 16 Clavier gates, qubit shuttling devices with more or fewer qubits, electron shuttle tiles, and/or Clavier gates can be fabricated. Alternatively, the qubits may be embedded within the shuttling array rather than around the periphery.

In other applications, a qubit shuttling device is incorporated into a quantum link to transport an electron from one register to another register along a non-linear path, where the path deviates from a straight line or order to avoid areas of low valley spitting or other undesirable features in the spin qubit heterostructure and/or to transport the electron between quantum registers in a complex quantum computer architecture.

Avoiding regions of low valley splitting or other undesirable features in the semiconductor of a quantum well during qubit shuttling is important to avoid leakage of quantum information stored in the qubit. The valley splitting problem in silicon qubits is due to the presence of two degenerate valleys near the Z point of the bulk band structure of Si. (F. A. Zwanenburg, et al., Rev. Mod. Phys. 85, 961(2013 ); M. Cardona et al., Phys. Rev. 142, 530(1966 ).) This leads to a small energy spacing between ground and excited valley states, called valley splitting. (Zwanenburg, et al., 2013; D. Buterakos et al., PRX Quantum 2, 040358 (2021).) When the energy splitting between valley states is comparable to the energy splitting between electron spin states that form the basis of the qubit, it causes decoherence in the qubits because the electrons can tunnel to the excited valley states with high probability through Landau-Zener transitions. Therefore, it is desirable to avoid regions of low valley splitting when transporting a spin qubit through a heterostructure.

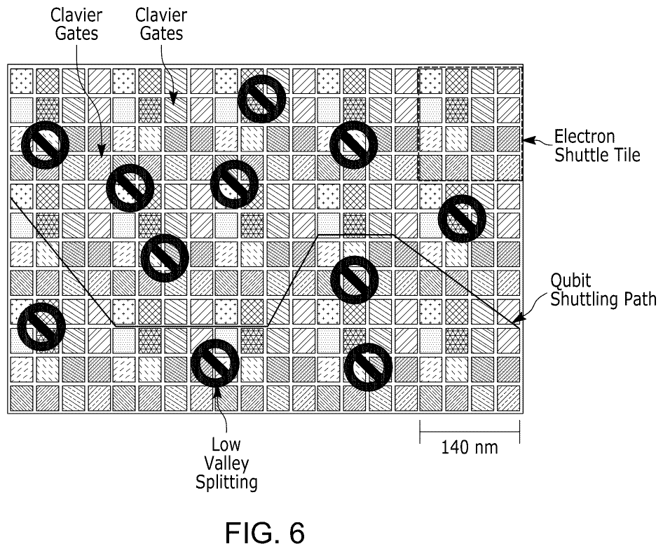

When a spin qubit shuttling device is used to shuttle an electron around low-valley-splitting regions in a semiconductor heterostructure, the valley splitting landscape in the heterostructure can be mapped out. Phase-shifted AC signals applied to the Clavier gate sets can then carry the electron around the low valley splitting regions. (Methods of mapping valley splittings in an Si/SiGe heterostructure are described in detail in Volmer, Mats, et al. “Mapping of valley splitting by conveyor-mode spin-coherent electron shuttling.” npj Quantum Information 10.1(2024 ): 61.) This is illustrated schematically in FIG. 6, which shows a spin qubit shuttling device comprising a 3-by-5 assembly of electron shuttle tiles. Regions of the underlying electron spin qubit heterostructure having a low valley splitting are indicated by a circle-backslash symbol, and the shuttling path of an electron through the underlying electron spin qubit heterostructure is shown with a solid line.

### Spin Qubit Shuttling Using Multiple Clavier Gate Channels

Another embodiment of the spin qubit shuttling devices transports qubits in two-lateral dimensions through two or more Clavier gate channels that are separated by a controllable tunneling barrier.

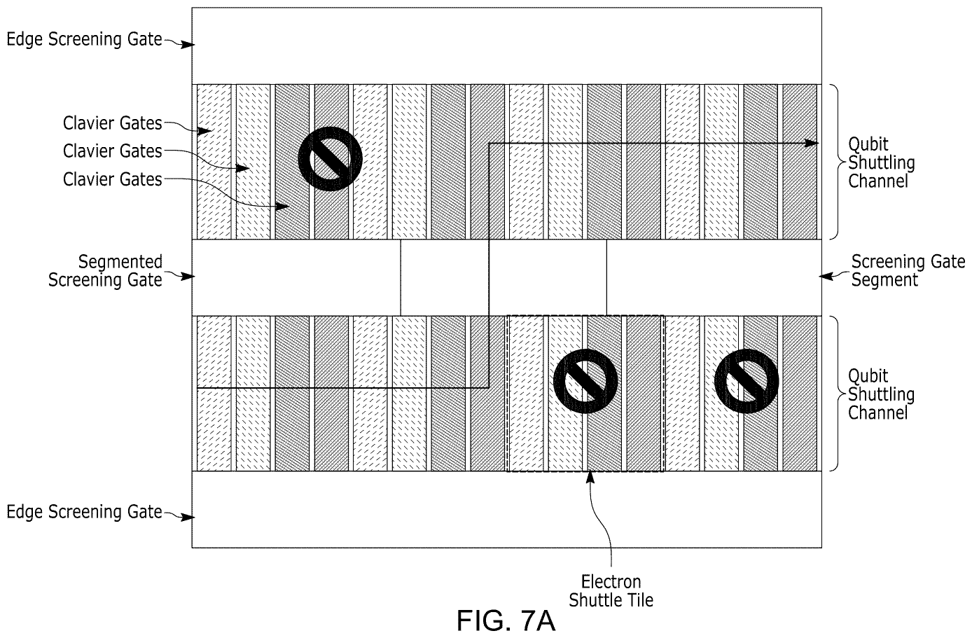

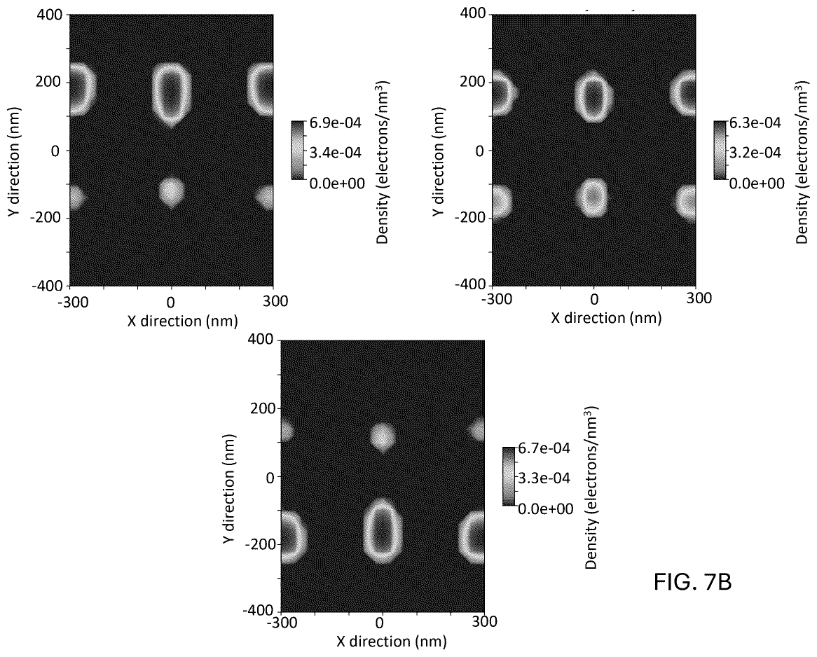

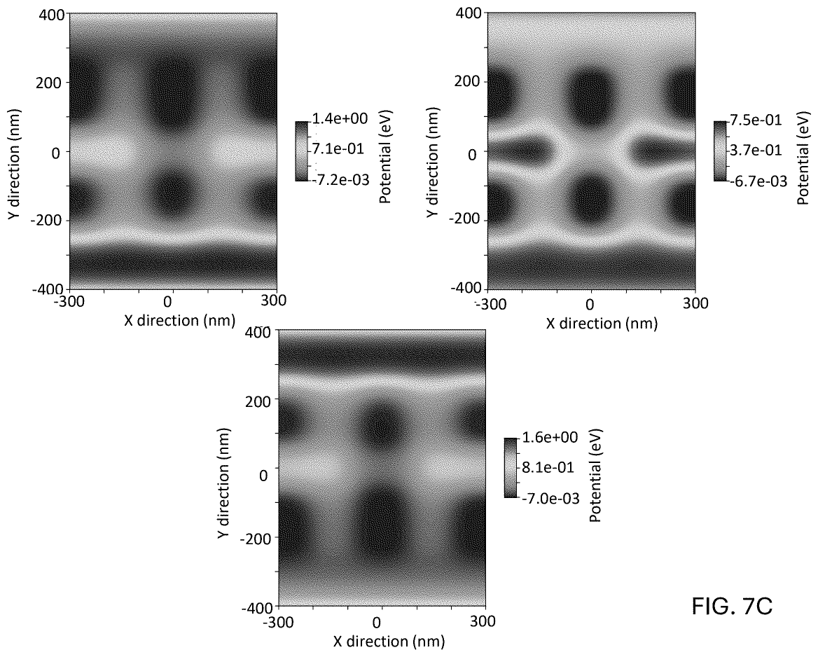

A schematic diagram of a basic embodiment of a spin qubit shuttling device having two shuttling channels is shown in FIG. 7A. The device includes an electron spin qubit heterostructure and a channel-forming series of electron shuttle tiles on the electron spin qubit heterostructure. Spin qubit heterostructures of the type used in the spin qubit shuttling devices based on 2D Clavier gate arrays can also be used in the spin qubit shuttling devices that use multiple Clavier gate channels.

The electron shuttle tiles in a series cover a length over which electrons in the spin qubit heterostructure are to be transported. The tiles are assembled in a side-by-side arrangement to provide the channels along which potential wells and the qubits contained therein are shuttled in the heterostructure.

Each electron shuttle tile includes a one-dimensional (1D) sequence of Clavier gates. A 1D sequence of Clavier gates differs from the 2D arrays of Clavier gates described above in that a sequence has multiple adjacent Clavier gates along one lateral direction (e.g., along the x-direction) but only a single Clavier gate along the other lateral direction (e.g., along the y-direction). The spin qubit shuttling device further includes three or more screening gates on the electron spin heterostructure, including two transverse edge gates and at least one central segmented screening gate. While the illustrative spin qubit shuttling device shown in FIG. 7A includes two shuttling channels with four shuttle tiles along the length of the channels, each tile having a sequence of four Clavier gates, devices with more than two shuttle channels can be fabricated by including more than one central segmented screening gate. Moreover, there may be more or fewer than four tiles along the length of each channel and the Clavier gate sequence within each tile may include more or fewer than four Clavier gates.

The Clavier gates in each tile are individually addressable and connected to a signal line through which AC signals are delivered. Each Clavier gate in an electron shuttle tile is connected to a corresponding Clavier gate in the other electron shuttle tiles to form a set of corresponding Clavier gates (“a Clavier gate set”). This is illustrated schematically in FIG. 7A, where Clavier gates shown with the same pattern form a Clavier gate set.

The Clavier gates are connected in a periodic signal matrix, whereby different phase-shifted AC signals are applied to different Clavier gate sets in the electron shuttle tile assembly. These phase-shifted AC voltage signals create potential wells in the spin qubit heterostructure that move along the length of the shuttling channels. In some embodiments, the phase shifted AC signals are phase-shifted sinusoidal signals. The generation of moving potential wells along a channel using phase-shifted sinusoidal signals is illustrated in Example 2. The potential wells formed along a channel are deep, symmetric, and well-separated, which minimizes or eliminates leakage of the electrons to other energy levels and tunneling of electrons between the potential wells, thereby maximizing the fidelity of the qubit shuttling process and enabling spin-coherent shuttling.

The application of gate voltages to the screening gates confines the electrons laterally within the channels. However, because the central screening gate is segmented-that is, it comprises multiple individually addressable gate segments along its length-the gate voltage applied to different gate segments can be adjusted to reduce the tunneling barrier potential at one or more locations between channels, thereby allowing lateral motion in an additional direction (e.g., in the y-direction) via quantum tunneling of an electron through the potential barrier separating the shuttling channels.

Snapshots of the electron density and the potential in the xy-plane of the spin qubit heterostructure of FIG. 7A at three different times are shown in FIG. 7B (electron density) and FIG. 7C (potential energy). (Details regarding the simulation used to generate these figures are provided in Example 2.) These figures illustrate the ability of the spin qubit shuttling devices to transport electron spin qubits over long distances in two dimensions using AC signals that are periodically varied along the length of qubit shuttle channels, while the tunnel barrier potential is adjusted by the application of gate voltages along a segmented screening contact to control (allow or disallow) electron tunneling between the channels.

The distances over which the qubit can be transported will depend on the dimensions of the Clavier gate sequences, the number of electron shuttle tiles along the shuttling channels, and the number of shuttling channels in the qubit shuttling device. By way of illustration, qubits may be shuttled along channels and/or between two or more channels over distances of at least 100 nm, at least 200 nm, at least 500 nm, at least 1 μm, at least 10 μm or further with high spin fidelity. High fidelity shuttling of the electrons can be carried out at relatively low velocities to minimize the leakage during shuttling. Generally, shuttling velocities of 5 m/s are sufficient, including shuttling velocities in the range from 1 m/s to 5 m/s. However, shuttling velocities outside of this range may be used.

The ability to transport electron spins along the length of and between qubit shuttling channels in a spin qubit heterostructures may be beneficial for a variety of reasons, including enabling the coupling of qubits that would otherwise be too distant to permit wavefunction overlap and avoiding regions of low valley splitting within a semiconductor quantum well of the spin qubit heterostructure, as described above with respect to the spin qubit shuttling devices based on 2D Clavier gate arrays. The use of a multi-channel spin qubit shuttling device to navigate spin qubits around regions of low valley splitting in a spin qubit heterostructure is illustrated schematically in FIG. 7A, where regions of the underlying electron spin qubit heterostructure having a low valley splitting are indicated by a circle-backslash symbol, and the shuttling path of an electron along and between the two channels is shown with a solid line.

In addition to the above-described components of the spin qubit shuttling devices, quantum computers incorporating the spin qubit shuttling devices will include other electronic components that are conventionally used to measure and control qubits and a conventional computer to control and program these electronic components. These components typically include a controller for controlling the qubits to perform a quantum computation and an output for providing a report generated using information obtained from the quantum computation performed. For example, a quantum computing system may include qubit circuitry, control hardware in communication with the qubit circuitry, and a controller for directing the control hardware to carry out various qubit manipulations and measurements, along with other operations. The system may also include an output for providing the quantum computation results. Quantum computing systems may be configured to operate at ultra-low temperatures, such as temperatures below a few degrees Kelvin, using a refrigeration unit.

The qubit circuitry may be configured to initialize a qubit, perform qubit transformations, and read out the final state of a qubit or qubits. For instance, the qubit circuitry may include one or more metallic gates configured to control charge confinement and states of quantum dots in a qubit register. In addition to gates, the qubit circuitry may also include one or more sensors coupled to the register configured for measuring qubit states.

The control hardware can include any number of electronic systems, hardware, or circuitry components capable of a wide range of functionality for controlling the qubit circuitry. For instance, the control hardware can include one or more voltage sources, current sources, microwave sources, spectrometers, signal generators, amplifiers, and so forth. Such control hardware may be configured to send, receive, and process a wide array of signals. For example, the control hardware may be configured to generate a number of pulsed voltages, or currents, to achieve pulsed gates for implementing qubit operations.

In general, the control hardware, as directed by the controller, may be used to prepare the qubit(s) formed in a heterostructure by the qubit circuitry. For instance, the control hardware may be configured to populate a qubit register with one or more electrons. The control hardware may perform a number of quantum logic operations, then readout the qubits(s), and report the quantum computation results obtained.

### EXAMPLES

### Example 1: Spin Qubit Shuttling Using Two-Dimensional Clavier Gate Arrays

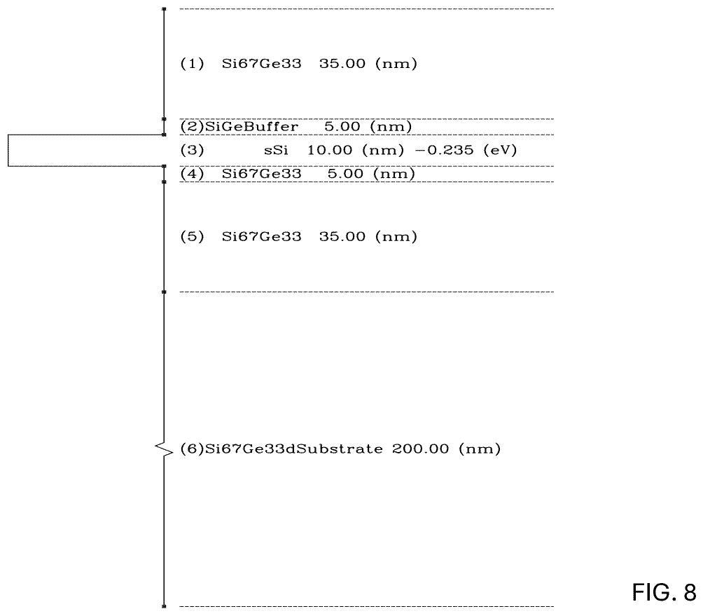

This Example illustrates the shuttling of spin qubits through a spin qubit heterostructure using a shuttling device composed of qubit shuttle tiles comprising 2D Clavier gate arrays. The spin qubit heterostructure used in this Example and in Example 2, below, is shown in FIG. 8.

To obtain the data shown in FIGS. 2A and 2B, Schrödinger-Poisson simulations of the device shown in FIGS. 1A and 1B were performed using the MaSQE software package. The vertical stack of this device is shown in FIG. 8. The voltage potential on each gate is the sum of two voltage potentials, V1 and V2, that vary sinusoidally in time, each with an amplitude of 100 mV. V1 was varied from gate to gate by changing the phase by 90 degrees for successive gates in the horizontal direction, and V2 was varied from gate to gate by modifying the phase by 90 degrees for successive gates in the vertical direction. To obtain the potentials in FIGS. 2A and 2B, the device was first solved with one electron per dot. The electron charge density was then removed, such that the potential landscape contained the effects of the electron images, but not the electrons themselves. FIGS. 3A and 3B are simulations of the same device, for which the sinusoidal potentials V1 and V2 were allowed to evolve to three different points in time, to demonstrate the motion of the pockets. Using the same vertical heterostructure stack, alternative gate layouts can be constructed, like that shown in FIG. 4A. The same software package, and an analogous sinusoidal voltage relationship, was used to generate FIGS. 4B and 4C.

### Example 2: Spin Qubit Shuttling Using Multiple Clavier Gate Channels

This Example illustrates the shuttling of spin qubits through a spin qubit heterostructure using a shuttling device composed of qubit shuttle channels comprising linear sequences of Clavier gates.

To obtain the data shown in FIGS. 7B and 7C, the MaSQE Schrödinger-Poisson software package was used. This time, the two-channel shuttling device shown in FIG. 7A was simulated. Assumed were Clavier gates with a single, sinusoidally varying voltage potential, V1, with 90 degree phase shifts on successive gates, and an amplitude of 100 mV. By modulating the potentials on the screening gates, asymmetric densities and potentials shown in FIGS. 7B and 7C were obtained, which induced tunneling between the channels.

The word “illustrative” is used herein to mean serving as an example, instance, or illustration. Any aspect or design described herein as “illustrative” is not necessarily to be construed as preferred or advantageous over other aspects or designs.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

What is claimed is:

1. A spin qubit shuttling device comprising:
a spin qubit heterostructure;
a two-dimensional assembly of shuttle tiles on the spin qubit heterostructure, each shuttle tile comprising a two-dimensional array of Clavier gates, wherein each Clavier gate in each shuttle tile is connected to a corresponding Clavier gate in each of the other shuttle tiles via a signal line, such that the connected, corresponding Clavier gates form a plurality of Clavier gate sets; and
one or more voltage sources configured to deliver AC signals to the Clavier gate sets via the signal lines, wherein the AC signal delivered to each Clavier gate set is phase-shifted with respect to the AC signals delivered to the other Clavier gate sets.

2. The spin qubit shuttling device of claim 1, further comprising:
a first screening gate along one edge of the two-dimensional assembly of shuttle tiles; and
a second screening gate along an opposing edge of the two-dimensional assembly of shuttle tiles.

3. The spin qubit shuttling device of claim 1, wherein the two-dimensional arrays of Clavier gates have dimensions of at least three Clavier gates by three Clavier gates.

4. The spin qubit shuttling device of claim 3, wherein the two-dimensional arrays of Clavier gates are four-by-four Clavier gate arrays.

5. The spin qubit shuttling device of claim 1, wherein the spin qubit heterostructure comprises a silicon quantum well layer, a germanium quantum well layer, or a silicon-germanium quantum well layer sandwiched between silicon-germanium barrier layers.

6. The spin qubit shuttling device of claim 1, wherein the Clavier gates have lateral dimensions in the range from 50 nm to 200 nm.

7. A quantum computing system comprising:
at least one spin qubit register or at least two spin qubit registers and a quantum link connecting the at least two qubit registers; and
a spin qubit shuttling device incorporated into at least one of the spin qubit registers or the quantum link, the spin qubit shuttling device comprising:
a spin qubit heterostructure;
a two-dimensional assembly of shuttle tiles on the spin qubit heterostructure, each shuttle tile comprising a two-dimensional array of Clavier gates, wherein each Clavier gate in each shuttle tile is connected to a corresponding Clavier gate in each of the other shuttle tiles via a signal line, such that the connected, corresponding Clavier gates form a plurality of Clavier gate sets; and
one or more voltage sources configured to deliver AC signals to the Clavier gate sets via the signal lines, wherein the AC signal delivered to each Clavier gate set is phase-shifted with respect to the AC signals delivered to the other Clavier gate sets.

8. A method of shuttling spin qubits using a spin qubit shuttling device comprising:
a spin qubit heterostructure;
a two-dimensional assembly of shuttle tiles on the spin qubit heterostructure, each shuttle tile comprising a two-dimensional array of Clavier gates, wherein each Clavier gate in each shuttle tile is connected to a corresponding Clavier gate in each of the other shuttle tiles via a signal line, such that the connected, corresponding Clavier gates form a plurality of Clavier gate sets; and
one or more voltage sources configured to deliver AC signals to the Clavier gate sets via the signal lines, wherein the AC signal delivered to each Clavier gate set is phase-shifted with respect to the AC signals delivered to the other Clavier gate sets, the method comprising:
applying gate potentials to the first screening gate and the second screening gate to form one or more spin qubits in the spin qubit heterostructure via electrostatic confinement of one or more electrons in the spin qubit heterostructure; and
delivering an AC signal to each Clavier gate set, wherein the AC signal delivered to each Clavier gate set is phase-shifted with respect to the AC signals delivered to the other Clavier gate sets, whereby the phase-shifted AC signals form potential wells that move in two lateral dimensions within the spin qubit heterostructure and transport the one or more spin qubits in two lateral dimensions through the spin qubit heterostructure.

9. The method of claim 8, wherein the phase-shifted AC signals are phase-shifted sinusoidal signals.

10. The method of claim 8, wherein the one or more spin qubits are transported over a distance of at least 100 nm.

11. The method of claim 8, wherein the one or more spin qubits are transported over a distance of at least 1μm.

12. The method of claim 8, wherein forming one or more spin qubits in the spin qubit heterostructure comprises forming a first qubit register in the spin qubit heterostructure and further wherein the moving potential wells transport one or more of the spin qubits in two lateral dimensions within the first qubit register.

13. The method of claim 8, wherein forming one or more spin qubits in the spin qubit heterostructure comprises forming a first qubit register and a second qubit register in the spin qubit heterostructure and further wherein the moving potential wells transport one or more of the spin qubits in two lateral dimensions from the first qubit register to the second qubit register.

14. The method of claim 8, wherein the spin qubit heterostructure comprises a silicon quantum well layer, a germanium quantum well layer, or a silicon-germanium quantum well layer sandwiched between silicon-germanium barrier layers.

15. The method of claim 14, further comprising mapping out a valley splitting landscape in the silicon quantum well layer or the silicon-germanium quantum well layer and controlling delivery of the phase-shifted AC signals to the Clavier gate sets to transport the one or more qubits in two dimensions around regions of low valley splitting in the silicon quantum well layer or the silicon-germanium quantum well layer.

16. A spin qubit shuttling device comprising:
a spin qubit heterostructure;
a one-dimensional series of shuttle tiles on the spin qubit heterostructure, each shuttle tile comprising a one-dimensional sequence of Clavier gates, wherein each Clavier gate in each shuttle tile is connected to a corresponding Clavier gate in each of the other shuttle tiles via a signal line, such that the connected, corresponding Clavier gates form a plurality of Clavier gate sets;
one or more voltage sources configured to deliver AC signals to the Clavier gate sets via the signal lines, wherein the AC signal delivered to each Clavier gate set is phase-shifted with respect to the AC signals delivered to the other Clavier gate sets;
a first transverse screening gate along an edge of the one-dimensional series of shuttle tiles;
a second transverse screening gate along an opposing edge of the one-dimensional series of shuttle tiles;
a segmented screening gate on the one-dimensional series of shuttle tiles and running between the first transverse screening gate and the second transverse screening gate, the segmented screening gate comprising a plurality of individually electronically addressable gate segments; and
one or more voltage sources configured to deliver gate voltages to the first and second transverse screening gates and the gate segments of the segmented screening gate.

17. A method of shuttling spin qubits using a spin qubit shuttling device comprising:
a spin qubit heterostructure;
a one-dimensional series of shuttle tiles on the spin qubit heterostructure, each shuttle tile comprising a one-dimensional sequence of Clavier gates, wherein each Clavier gate in each shuttle tile is connected to a corresponding Clavier gate in each of the other shuttle tiles via a signal line, such that the connected, corresponding Clavier gates form a plurality of Clavier gate sets;
one or more voltage sources configured to deliver AC signals to the Clavier gate sets via the signal lines, wherein the AC signal delivered to each Clavier gate set is phase-shifted with respect to the AC signals delivered to the other Clavier gate sets;
a first transverse screening gate along an edge of the one-dimensional series of shuttle tiles;
a second transverse screening gate along an opposing edge of the one-dimensional series of shuttle tiles;
a segmented screening gate on the one-dimensional series of shuttle tiles and running between the first transverse screening gate and the second transverse screening gate, the segmented screening gate comprising a plurality of individually electronically addressable gate segments;
one or more voltage sources configured to deliver gate voltages to the first and second transverse screening gates and the gate segments of the segmented screening gate, the method comprising:
applying gate potentials to the first transverse screening gate, the second transverse screening gate, and the gate segments of the segmented screening gate to define a first shuttle channel between the first transverse screening gate and the segmented screening gate and a second shuttle channel between the segmented screening gate and the second transverse screening gate and to form one or more spin qubits in the spin qubit heterostructure via electrostatic confinement of one or more electrons in the first and second shuttle channels;
delivering an AC signal to each Clavier gate set, wherein the AC signal delivered to each Clavier gate set is phase-shifted with respect to the AC signals delivered to the other Clavier gate sets, whereby the phase-shifted AC signals form potential wells that move along the first and second channels within the spin qubit heterostructure and transport the one or more spin qubits in one dimension through the spin qubit heterostructure along the first and second channels; and
adjusting the gate potential applied to the gate segments of the segmented screening gate to reduce a tunneling potential between the first and second channels, whereby one or more spin qubits move laterally between the first and second channels via quantum tunneling of one or more of the electrons.

18. The method of claim 17, wherein the phase-shifted AC signals are phase-shifted sinusoidal signals.

19. The method of claim 18, wherein the spin qubit heterostructure comprises a silicon quantum well layer, a germanium quantum well layer, or a silicon-germanium quantum well layer sandwiched between silicon-germanium barrier layers.

20. The method of claim 19, further comprising mapping out a valley splitting landscape in the silicon quantum well layer or the silicon-germanium quantum well layer and controlling delivery of the phase-shifted AC signals to the Clavier gate sets and the gate potentials applied to the gate segments to transport the one or more qubits in two dimensions around regions of low valley splitting in the silicon quantum well layer or the silicon-germanium quantum well layer.
